(19) United States
(12) Patent Application Publication
(10) Pub. No.: US 2011/0311874 A1
(43) Pub. Date: Dec. 22, 2011

(54) Silicon-Carbon Nanostructured Electrodes

(75) Inventors: Chongwu Zhou, Arcadia, CA (US); Po-Chiang Chen, Hillsboro, OR (US); Jing Xu, Los Angeles, CA (US); Haitian Chen, Los Angeles, CA (US)

(73) Assignee: UNIVERSITY OF SOUTHERN CALIFORNIA, Los Angeles, CA (US)

(21) Appl. No.: 13/099,211

(22) Filed: May 2, 2011

Related U.S. Application Data
(60) Provisional application No. 61/329,986, filed on Apr. 30, 2010.

(51) Int. Cl. H01M 4/583; C23C 14/34; B82Y 40/00; B82Y 99/00

(52) U.S. Cl. 429/231.8; 204/192.1; 977/890; 977/948

(57) ABSTRACT

Hybrid silicon-carbon nanostructured electrodes are fabricated by forming a suspension including carbon nanostructures and a fluid, disposing the suspension on a substrate, removing at least some of the fluid from the suspension to form a carbon nanostructure layer on the substrate, and sputtering a layer of silicon over the carbon nanostructure layer to form the hybrid silicon-carbon nanostructured electrode. Sputtering the layer of silicon facilitates fabrication of large dimension electrodes at room temperature. The hybrid silicon-carbon nanostructured electrode may be used as an anode in a rechargeable battery, such as a lithium ion battery.

### CROSS-REFERENCE TO RELATED APPLICATION

This application claims priority to U.S. Application Ser. No. 61/329,986, filed on Apr. 30, 2010, which is incorporated herein by reference.

### FEDERALLY SPONSORED RESEARCH OR DEVELOPMENT

The invention was made with government support under Computing and Communication Foundations Grant Nos. CCF 0726815 and CCF 0702204 awarded by the National Science Foundation. The government has certain rights in the invention.

### TECHNICAL FIELD

This invention relates to silicon-carbon nanostructures and devices including silicon-carbon nanostructured electrodes.

### BACKGROUND

Silicon (Si) nanowires, including hybrid core-shell nanowires, have been used as anode materials for lithium ion batteries. Nanostructured carbon-silicon composites formed in high-temperature processes have also been used as anode materials for lithium ion batteries.

### SUMMARY

In a first aspect, fabricating a hybrid silicon-carbon nanostructured electrode includes forming a suspension including carbon nanostructures and a fluid, disposing the suspension on a substrate, removing at least some of the fluid from the suspension to form a carbon nanostructure layer on the substrate, and sputtering a layer of silicon over the carbon nanostructure layer to form the hybrid silicon-carbon nanostructured electrode.

In a further aspect according to the first aspect, the substrate includes a conductive foil.

In a further aspect according to the first aspect, the substrate includes a filter membrane. In some implementations, the carbon nanostructure layer is removed from the filter membrane before sputtering the layer of silicon over the carbon nanostructure layer.

In a further aspect according to the first aspect, the sputtering occurs at room temperature.

In a further aspect according to the first aspect, the sputtering occurs in an inert atmosphere.

In a further aspect according to the first aspect, the carbon nanostructures include carbon nanofibers, carbon nanotubes, or a combination thereof.

In a further aspect according to the first aspect, the fluid includes an organic solvent.

In a further aspect according to the first aspect, the suspension is a slurry.

In a further aspect according to the first aspect, the suspension is an aqueous suspension.

In a further aspect according to the first aspect, the suspension further includes a surfactant.

In a further aspect according to the first aspect, the carbon nanostructure layer includes Buckypaper.

In a further aspect according to the first aspect, a thickness of the silicon layer is at least 100 nm and less than 500 nm.

In a further aspect according to the first aspect, the layer of silicon forms a continuous layer over the carbon nanostructure layer.

In a further aspect according to the first aspect, the hybrid silicon-carbon nanostructured electrode is substantially free of binder materials.

In a further aspect according to the first aspect, the hybrid silicon-carbon nanostructured electrode is substantially free of conductive additives.

In a further aspect according to the first aspect, wherein a surface area of the substrate over which the suspension is disposed is at least 25 in².

A further aspect according to the first aspect includes an electrode for a lithium ion battery, the electrode including the hybrid silicon-carbon nanostructured electrode.

A further aspect according to the first aspect includes a battery including an anode, the anode including the hybrid silicon-carbon nanostructured electrode.

A further aspect according to the first aspect includes a battery. The battery includes one or more electric connection locations, an anode coupled with the one or more electric connection locations, and a cathode coupled with the one or more electric connection locations. At least one of the anode or the cathode includes the hybrid silicon-carbon nanostructure.

These general and specific aspects may be implemented using a device, system or method, or any combination of devices, systems, or methods. The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 depicts formation of a hybrid silicon-carbon nanostructure.

FIG. 2 depicts formation of a hybrid silicon-carbon nanostructured electrode.

FIGS. 3A and 3B show scanning electron microscope (SEM) images of single-walled carbon nanotubes before and after coating with silicon, respectively.

FIGS. 4A and 4B show photographs of carbon nanofibers (CNFs) on a copper foil before and after deposition of a 200 nm layer of silicon, respectively. The insets show SEM images of the CNF surface and the silicon surface, respectively.

FIG. 5 shows a SEM image of sputtered silicon on a CNF layer.

FIGS. 6A and 6B show a side view of a CNF layer before and after deposition of a 500 nm layer of silicon.

FIG. 7 shows a cyclic voltammogram for 200 nm silicon on a CNF layer.

FIG. 8 shows voltage profile for first 90 cycles of a 200 nm sputtered Si/CNF anode at a constant charging/discharging current of 0.05 A/g.

FIG. 9 shows voltage profile for the first cycle of the 100 nm, 200 nm, 300 nm, and 500 nm Si/CNF anodes at a constant charging/discharging current of 0.05 A/g.

FIG. 10 shows discharge capacity of 100 nm, 200 nm, and 300 nm sputtered Si/CNF anodes, and 200 nm Si/Cu anodes at current rate C/10.

FIG. 11 shows discharge capacity of a 300 nm sputtered Si/CNF anode at current rate C/4.

FIG. 12 shows Coulombic efficiency of a 200 nm sputtered Si/CNF anode.

FIG. 13 shows a SEM image of the surface of a 200 nm sputtered Si/CNF anode after 95 charging/discharging cycles.

FIG. 14 shows an energy-dispersive X-ray spectroscopy (EDS) spectrum of a 200 nm sputtered Si/CNF anode after 95 charging/discharging cycles.

### DETAILED DESCRIPTION

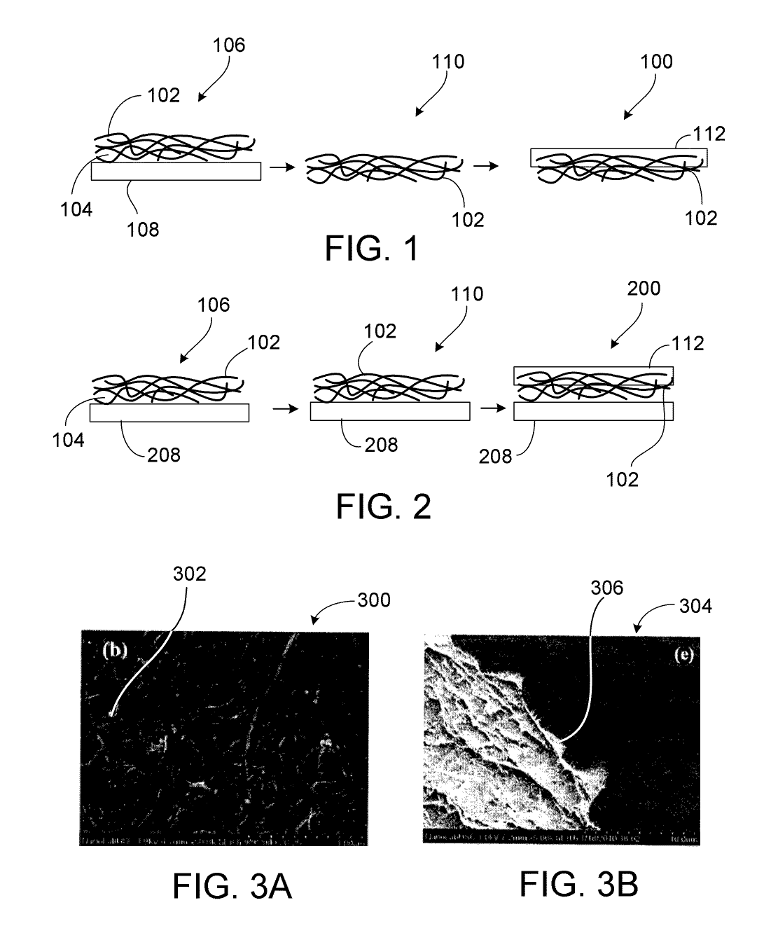

Referring to FIG. 1, hybrid silicon-carbon nanostructured electrode 100 is fabricated by mixing carbon nanostructures 102 with fluid 104 to form suspension 106. One or more additives including surfactants such as sodium dodecyl sulfate and sodium lauryl sulfate may be included in suspension 106. Suspension 106 is filtered on a filter membrane 108 to form carbon nanostructure layer 110. Carbon nanostructure layer 110 may be, for example, a network of carbon nanostructures 102. Before filtering, suspension 106 may be agitated (e.g., mechanically or ultrasonically) to separate out undissolved carbon nanostructure bundles and impurities. Carbon nanostructure layer 110 may be, for example, Buckypaper. Carbon nanostructure layer 110 is removed from the filter. Silicon is deposited on carbon nanostructure layer 110 in a sputtering process to form silicon layer 112 on carbon nanostructures 102. Silicon layer 112 may be an amorphous silicon (a-Si) layer. Hybrid silicon-carbon nanostructured electrode 100 may be formed without the addition of binder materials and without conductive additives. That is, hybrid silicon-carbon nanostructured electrode 100 is substantially free of binder materials and conductive additives. Additionally, the nature of sputtering, in combination with other features of hybrid silicon-carbon nanostructured electrode 100, contributes to advantages including scalable fabrication of electrodes, electrodes having increased surface area, and room temperature fabrication.

Referring to FIG. 2, hybrid silicon-carbon nanostructured electrode 200 is fabricated by mixing carbon nanostructures 102 with fluid 104, forming suspension 106, and spreading the suspension on conductive foil 208. In certain cases, suspension 106 is a slurry. One or more additives including surfactants such as sodium dodecyl sulfate and sodium lauryl sulfate may be included in suspension 106. Suspension 106 is allowed to dry at least partially to form carbon nanostructure layer 110. Carbon nanostructure layer 110 may be, for example, a network of carbon nanostructures 102. Silicon is deposited on carbon nanostructure layer 110 in a sputtering process to form amorphous silicon layer 112 on carbon nanostructures 102. Hybrid silicon-carbon nanostructured electrode 200 may be formed without binder materials and without conductive additives.

Examples of carbon nanostructures that can be used to form hybrid silicon-carbon nanostructures include carbon nanofibers (CNFs) and single-walled carbon nanotubes (SWNTs). The fluid for forming the slurry can be a liquid having one or more components such as, for example, water, organic solvents including polyvinylidene fluoride (PVDF) and N-methylpyrrolidone (NMP). The conductive foil may be formed of metals or alloys including copper, titanium, and nickel. In some cases, the CNF layer has a thickness in a range from about 30 μm to about 30 μm.

Silicon layer 112 is deposited at room temperature (e.g., at a temperature in a range from about 20° C. to about 26° C.) in an inert atmosphere at a pressure, for example, of several millibar. The inert atmosphere may include argon, nitrogen, or a mixture thereof. A thickness of the sputtered silicon layer may be in a range from about 50 nm to about 500 nm.

Hybrid silicon-carbon nanostructured electrodes 100 and 200 can be used as thin film electrodes. In an example, hybrid silicon-carbon nanostructured electrodes 100 and 200 are used as anodes in a lithium-ion battery. Lithium ion batteries are understood to include an anode, a cathode, an electrical pathway therebetween, and an electrolyte between the anode and the cathode. The carbon nanostructure layer in a hybrid silicon-carbon nanostructured electrode can function to provide one or more features including mechanical support, stress/strain relaxation, and an electron conducting pathway during, for example, lithium intercalation. The metal foil, the carbon nanostructure layer, or both may function as a current collecting electrode. The silicon layer can store electric energy. Coulombic efficiency of hybrid silicon-carbon nanostructured electrode 100 can be at least 90% or at least 92% for a first lithiation cycle, and at least 93% or at least 95% for subsequent lithiation cycles.

In an example, arc-discharge carbon nanotubes (P3-SWNT from Carbon Solutions, Inc.) were mixed with 1 wt % aqueous sodium dodecyl sulfate (SDS) in distilled water to make a dense SWNT suspension with a concentration of about 0.1 mg/mL. The SWNT suspension was then ultrasonically agitated using a probe sonicator for about 20 minutes, followed by centrifugation to separate out undissolved SWNT bundles and impurities. The SWNT suspension was filtered through a porous alumina filtration membrane (Anodisc, pore size: 200 nm, Whatman Ltd.). As the solvent went through the membrane, SWNTs were trapped on the membrane surface and formed an entangled network. After filtration, distilled water was applied to remove SDS from the nanotubes. After the trapped SWNT film had dried to form Buckypaper, the Buckypaper (about 0.5 cm²) was peeled off the filtration membrane. The mass of SWNT Buckypaper was determined by a micro-balance after filtration. Mass loading of a 2-inch-diameter SWNT Buckpaper was about 8 mg, with a film thickness of 2.2 μm and sheet resistance of 13-16Ω. FIG. 3A shows a scanning electron microscope (SEM) image of SWNT layer 300 with SWNTs 302 after removal from the filtration membrane.

A silicon layer was deposited with a conventional sputtering system at a deposition rate of 6 nm/min at room temperature in an argon environment at a pressure of about 1×10⁻⁶ Torr. FIG. 3B shows a SEM image of hybrid silicon-carbon nanostructured electrode 304 with silicon layer 306. As seen in FIG. 3B, silicon layer 306 forms a continuous layer over the SWNTs. The thickness of the SWNT layer is about 300 nm. To observe the interface between SWNT layer 300 and silicon layer 306, the silicon surface of hybrid silicon-carbon nanostructured electrode was scratched. The SWNT layer underneath the silicon layer was clearly observed, and the sputtered silicon formed a homogenous film on the SWNT layer.

After silicon deposition, the SWNT Buckypaper served as a current collecting electrode, and the SWNTs functioned as active material in the absence of binding or conductive additives. Electrochemical measurements were carried out with a battery testing system (MSTAT, Arbin) in 1 M LiCl0₄ electrolyte (in ethylene carbonate (EC)/diethylene carbonate (DEC)). Galvanostatic (GV) charging/discharging measurements were used to determine the specific capacity (Cₛₚ), and Coulombic efficiency of the devices in a two-electrode configuration.

In another example, carbon nanofibers (Sigma-Aldrich) were mixed with polyvinylidene fluoride (PVDF, 10% weight) in N-methylpyrrolidone (NMP) to form a slurry, and then spread onto copper foil using a stainless steel blade. To remove PVDF from the CNFs, the CNF slurry/copper foil was heated in a furnace in an argon environment (15 Torr) at 700° C. for 2 hours. The loading density of the CNF films was measured to be about 8 mg/cm². The CNF/copper foil was then placed in a sputtering system (Denton Discovery Sputtering System) for silicon deposition.

The silicon deposition on CNFs was carried out in an argon environment at room temperature and a pressure of about 1×10⁻⁶ Torr, with a deposition rate of 6 nm/min and deposition thicknesses of 100 nm, 200 nm, 300 nm, and 500 nm. As a comparative example, 200 nm of silicon was sputtered directly on to a copper foil. The hybrid silicon-carbon nanostructured electrodes were then characterized by using field-emission scanning electron microscope (FE-SEM, Hitachi S-4800) and energy-dispersive X-ray spectroscopy (EDS, Jeol, JSM-7001F). CR2032 coin cells were assembled in an argon-filled glove box by using the hybrid silicon-carbon nanostructured electrodes as working electrodes and lithium metal foil as counter electrodes. 1M LiClO₄ dissolved in a 1:1 (weight ratio) mixture of ethylene carbonate (EC) and diethyl carbonate (DEC) was used as the electrolyte.

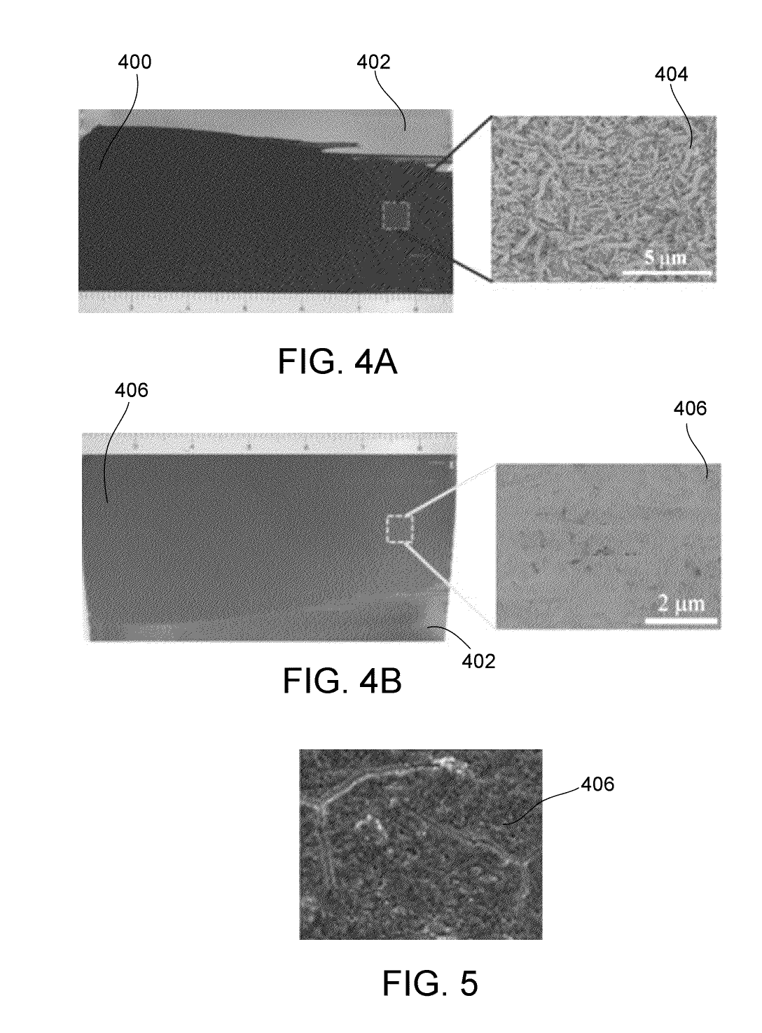

FIG. 4A is a photograph of a CNF layer 400 on copper foil 402 before silicon deposition. The inset shows a top-view SEM image of carbon nanostructure layer 404 before silicon deposition. FIG. 4B is a photograph of a CNF layer on copper foil 402 after sputtering deposition of a 200 nm thick silicon layer 406. The inset shows a top-view SEM image of silicon layer 406. The area of silicon deposition was about 8.5 in×3 in. After silicon deposition, the topography of CNFs was covered by a continuous silicon layer or film to form a hybrid Si—CNF nanostructure or thin film electrode.

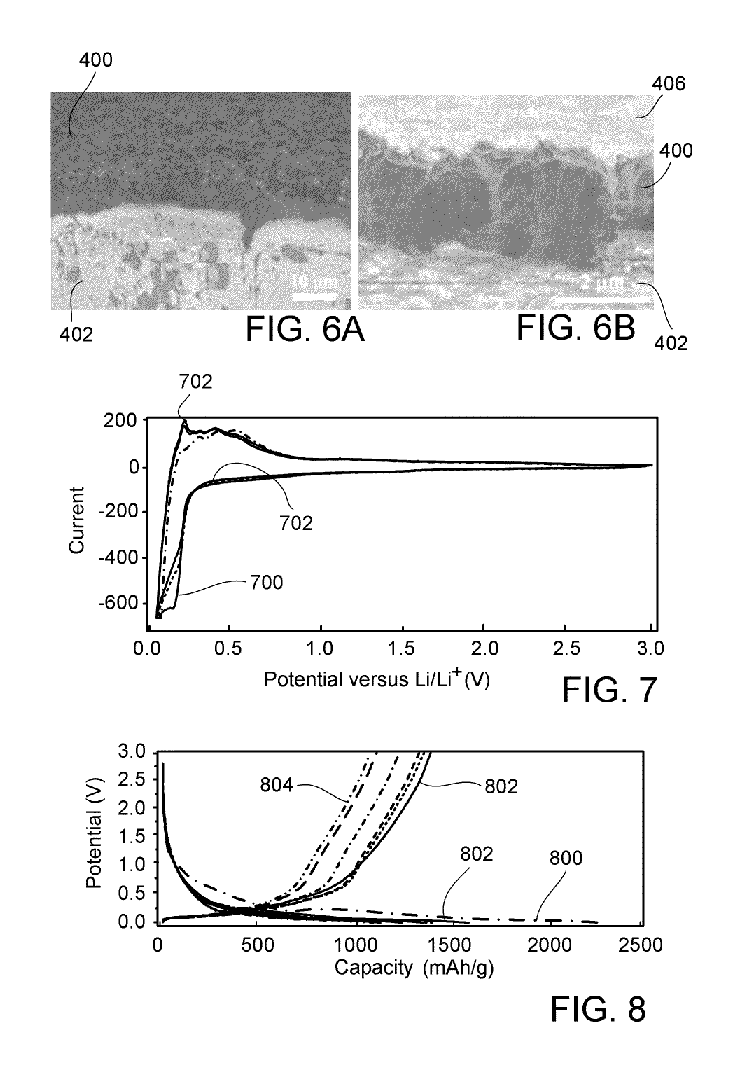

The surface of the Si/CNF hybrid film was scratched to reveal the interface between the CNFs and the silicon. FIG. 5 shows a front-view SEM image of sputtered silicon 406 on the CNF layer. A uniform layered structure of sputtered silicon and CNFs is observed. The thickness of the sputtered Si layer shown in FIG. 5 is about 500 nm. FIGS. 6A and 6B show SEM and EDS images, respectively, of sputtered Si/CNF electrodes, with silicon layer 406 on CNF layer 400 and copper foil 402. Silicon layer 406 appears to form a uniform coating or layer on the CNF layer.

Electrochemical measurements of sputtered Si/CNF anodes were carried out with a battery testing system (MSTAT, Arbin) and a potentiostat (Gamry, Reference 600). The cyclic voltammetry (CV) profiles of sputtered Si/CNF anodes were performed with the Si/CNF electrode as the working electrode, and lithium foil as the reference electrode.

FIG. 7 shows the first three CV curves of a sputtered Si/CNF anode with a deposited silicon thickness of 200 nm, in a potential window of 0.01 V and 3.0 V, with a scan rate of 0.05 mV/sec. Two pairs of signature redox peaks of amorphous silicon are seen around 0.18/0.03 V (reduction) and around 0.50/0.30 V (oxidation) in the first cycling curve (plot 700), indicative of Si—Li reactions in the sputtered Si/CNF anode. The shape of the first cycling curve differs from that of the second and the third curves (plots 702 and 704, respectively), in which the sharp peak at 0.18 V disappears and the peaks at 0.50/0.30 V shift toward a lower potential. The irreversible reaction of the first cycle may be attributed to the formation of a solid electrolyte interface (SEI) layer or the phase transformation. However, similarity of the second and the third cycles suggests that the system reached a steady state.

Galvanostatic (GV) charging/discharging measurements were used to determine the specific capacity (Cₛₚ), and the Coulombic efficiency of the devices in a two-electrode configuration. FIG. 8 shows the cycling performance of a 200 nm sputtered Si/CNF anode up to 95 cycles, with a constant charging/discharging current of 0.05 A/g. In the initial state, the potential dropped to 0.22 V and maintained a flat plateau at around 0.25 V, then gradually decreased to 0.01 V. The capacity in the first discharging process of sputtered Si/CNF anodes (plot 800) is about 2,320 mAh/g. The Coulombic efficiency of this device in the first cycle is about 88%. The second discharging capacity (plot 802) dropped to 1,608 mAh/g. After the first cycle, the reversible charging-discharging reactions are substantially the same for the subsequent 80 cycles. Several cycles are shown between the second cycle (plot 802) and the ninetieth cycle (plot 804).

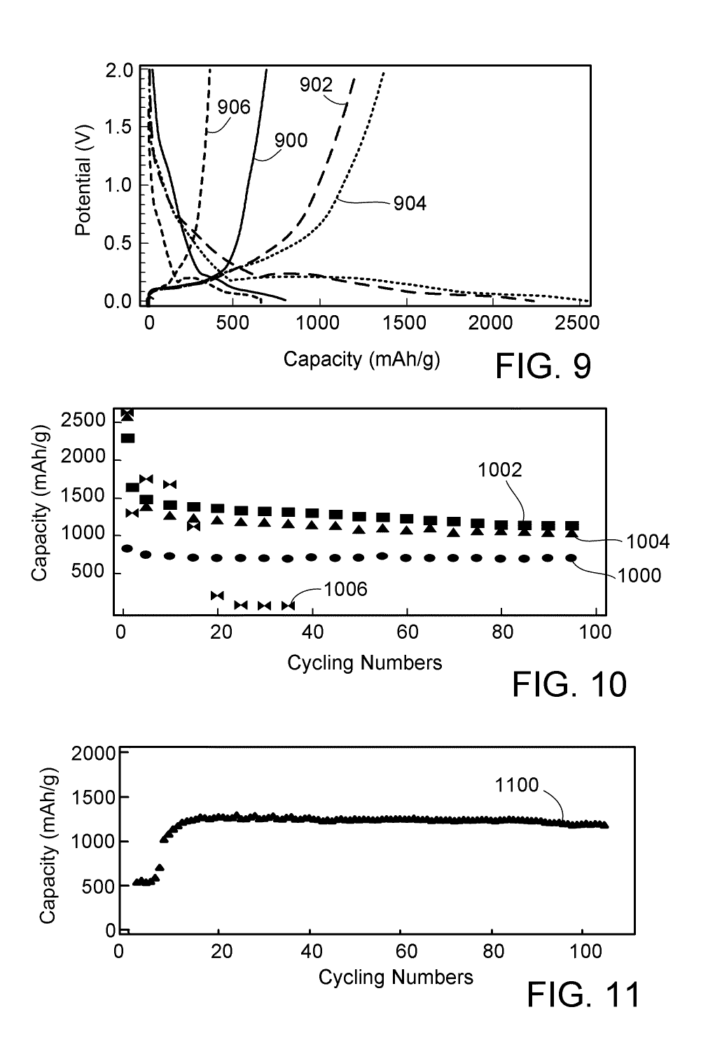

To further understand the GV behaviors of sputtered Si/CNF anodes, Si/CNF anodes were prepared with a range of silicon layer thicknesses (100 nm, 300 nm, and 500 nm). GV measurements were performed on the prepared Si/CNF anodes with a constant charging/discharging current of 0.05 A/g. The first cycle of these Si/CNF anodes is shown in FIG. 9. The voltage profile of 100 nm sputtered Si/CNF anode (plot 900) differs from that of 200 nm (plot 902), 300 nm (plot 904), and 500 nm (plot 906) sputtered Si/CNF anodes. The plateau at 0.22 V is short and not easily observed, and the discharging capacity is 786 mAh/g. With more silicon deposition, both 300 nm and 500 nm sputtered Si/CNF anodes exhibit longer plateaus at around 0.21 V. The 300 nm sputtered Si/CNF anode shows a high discharging capacity of 2,528 mAh/g, which is more than three times higher than that of the 100 nm sputtered Si/CNF anode. The discharging capacity of the 500 nm sputtered Si/CNF anode is 648 mAh/g.

FIG. 10 shows capacity versus cycling numbers with sputtered silicon thicknesses of 100 nm (plot 1000), 200 nm (plot 1002), and 300 nm (plot 1004). The 100 nm Si/CNF anode displays a capacity retention of about 84% after 95 cycles. For 200 nm Si/CNF anodes, the capacity retention is about 80%. Good capacity retention was also observed even at a higher charging/discharging rate (C/4).

In a comparative experiment, a 200 nm silicon layer was directly sputtered on copper foil (Si/Cu) and used as a reference electrode. GV measurements were carried out. As seen in FIG. 10 (plot 1006), the Si/Cu anode shows low capacity retention. After 20 cycles, there was almost no measurable capacity from the anode, suggesting loss of active material.

FIG. 11 shows specific capacity of up to 1200 mAh/g after 105 cycles for a 300 nm Si/CNF anode (plot 1100), or 90% capacity retention. In the initial stage of the cycle test, a reduced capacity was observed. After about 10 cycles, the capacity recovered to about 1200 mAh/g.

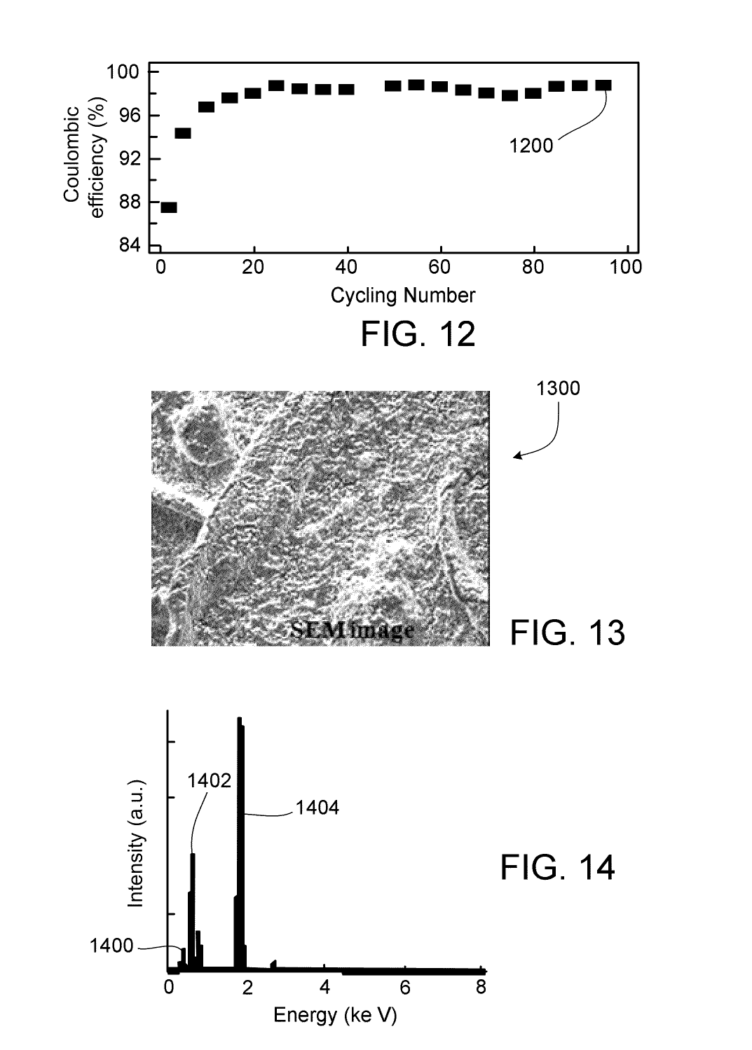

FIG. 12 shows the Coulombic efficiency of a 200 nm sputtered Si/CNF anode (plot 1200). The cell exhibits a first cycle Coulombic efficiency of 88%. The Coulombic efficiency of the second cycle increases to 93%, and then stays between 96-99% for the next 80 cycles. Similar Coulombic efficiency was also observed for 100 nm and 300 nm sputtered Si/CNF anodes.

FIG. 13 shows an SEM image of a 200 nm sputtered Si/CNF electrode 1300 after 95 charging/discharging cycles. No evidence of loss of adhesion between the silicon and the CNFs is apparent. The silicon surface appears to have a rough texture after 95 cycles. This rough texture is thought to result at least in part from the lithiation/delithiation process. EDS images of sputtered Si/CNF electrodes suggest that the sputtered silicon layer is adhered to the CNFs even after a large number of cycling experiments. FIG. 14 shows an EDS spectrum of sputtered Si/CNF electrodes, with carbon, oxygen, and silicon peaks indicated by reference numbers 1400, 1402, and 1404, respectively.

As described herein, hybrid silicon-carbon nanostructured electrodes with an area of about 25 in² have been fabricated and used as electrodes (e.g., anodes) in lithium ion batteries. The amorphous-silicon (a-Si) deposited by sputtering works as the active material to store electric energy, and the coated carbon nanofibers (CNFs) serve as an electron conducting pathway and strain/stress relaxation layer to the sputtered a-Si layers during the intercalation process of lithium ions. The fabricated lithium ion batteries, with a deposited a-Si thickness of 200 nm and 300 nm, exhibit a high specific capacity (greater than 2,000 mAh/g or greater than 2500 mAh/g), and also show good capacity retention (over 80%) and Coulombic efficiency (greater than 88% for the first cycle and over 98% in the following cycles) after a large number of charging/discharging experiments (over 90 or over 100).

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A method comprising:
forming a suspension comprising carbon nanostructures and a fluid;
disposing the suspension on a substrate;
removing at least some of the fluid from the suspension to form a carbon nanostructure layer on the substrate; and
sputtering a layer of silicon over the carbon nanostructure layer to form a hybrid silicon-carbon nanostructured electrode.

2. The method of claim 1, wherein the substrate comprises a conductive foil.

3. The method of claim 1, wherein the substrate comprises a filter membrane.

4. The method of claim 3, further comprising removing the carbon nanostructure layer from the filter membrane before sputtering the layer of silicon over the carbon nanostructure layer.

5. The method of claim 1, wherein the sputtering occurs at room temperature.

6. The method of claim 1, wherein the sputtering occurs in an inert atmosphere.

7. The method of claim 1, wherein the carbon nanostructures comprise carbon nanofibers, carbon nanotubes, or a combination thereof.

8. The method of claim 1, wherein the fluid comprises an organic solvent.

9. The method of claim 1, wherein the suspension is a slurry.

10. The method of claim 1, wherein the suspension is an aqueous suspension.

11. The method of claim 1, wherein the suspension further comprises a surfactant.

12. The method of claim 1, wherein the carbon nanostructure layer comprises Buckypaper.

13. The method of claim 1, wherein a thickness of the silicon layer is at least 100 nm and less than 500 nm.

14. The method of claim 1, wherein the layer of silicon forms a continuous layer over the carbon nanostructure layer.

15. The method of claim 1, wherein the hybrid silicon-carbon nanostructured electrode is substantially free of binder materials.

16. The method of claim 1, wherein the hybrid silicon-carbon nanostructured electrode is substantially free of conductive additives.

17. The method of claim 1, wherein a surface area of the substrate over which the suspension is disposed is at least 25 in².

18. An electrode for a lithium ion battery, the electrode comprising the hybrid silicon-carbon nanostructured electrode of claim 1.

19. A battery comprising an anode, wherein the anode comprises the hybrid silicon-carbon nanostructured electrode of claim 1.

20. A battery comprising:
one or more electric connection locations;
an anode coupled with the one or more electric connection locations; and
a cathode coupled with the one or more electric connection locations;
wherein at least one of the anode or the cathode comprises a hybrid silicon-carbon nanostructure produced according to the method of claim 1.
